(19) United States
(12) Patent Application Publication
(10) Pub. No.: US 2025/0174586 A1
(43) Pub. Date: May 29, 2025

(54) SEMICONDUCTOR STRUCTURE HAVING OPTICAL COMPONENT AND MANUFACTURING METHOD THEREOF

(71) Applicant: Taiwan Semiconductor Manufacturing Company, Ltd., Hsinchu (TW)

(72) Inventors: Chia-Hui Lin, Taichung County (TW); Chen Chen, New Taipei City (TW); Chih-Hao Yu, Tainan City (TW); Wei-Ming Wang, Taichung City (TW); Ren-Fen Tsui, New Taiepi City (TW); Chen-Hua Yu, Hsinchu City (TW)

(73) Assignee: Taiwan Semiconductor Manufacturing Company, Ltd., Hsinchu (TW)

(21) Appl. No.: 18/519,047

(22) Filed: Nov. 26, 2023

(51) Int. Cl. H01L 23/00; H01L 23/31; H01L 25/065

(52) U.S. Cl. CPC H01L 24/08; H01L 23/3178; H01L 24/03; H01L 25/0657; H01L 2224/03011; H01L 2224/0384; H01L 2224/08147; H01L 2225/06548; H01L 2924/14

(57) ABSTRACT

A semiconductor structure includes a substrate, a bonding structure disposed over the substrate, and a filling layer. The substrate includes an optically active region and an optical surface in the optically active region. The bonding structure includes a bonding dielectric layer and conductive features in the bonding dielectric layer and arranged outside a keep-out zone of the bonding structure, where in a first view, the keep-out zone is located in the optically active region, and a first feature of the conductive features is disposed between the optically active region and the keep-out zone. The filling layer is interposed between the bonding structure and the optically active region of the substrate. The first feature is separated from the filling layer by the bonding dielectric layer in a second view.

### BACKGROUND

Currently, semiconductor structures including both photonic integrated circuit (PIC) dies and electronic integrated circuit (EIC) dies are becoming increasingly popular for their compactness. In addition, due to the widely use of optical fiber-related applications for signal transmission, optical signaling and processing have been used in more applications. Although existing methods of fabricating a semiconductor structure with an optical component have been generally adequate for their intended purposes, they have not been entirely satisfactory in all respects. For example, challenges rise to develop robust process for coupling PIC dies and EIC dies, while improving the pitch and density of the bonding features.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1G illustrate schematic cross-sectional views of intermediate steps during a process for forming a first device according to some embodiments.

FIG. 1H illustrates a schematic and partial top-down plan view of a first device according to some embodiments.

FIG. 2 illustrates a schematic cross-sectional view of forming a semiconductor structure with the first die bonded to a second die according to some embodiments.

FIGS. 3A and 3B illustrate schematic cross-sectional views of the semiconductor structure optically coupled to an optical signal port according to some embodiments.

FIG. 4 illustrates a schematic cross-sectional view of a semiconductor structure optically coupled to an optical signal port according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure are discussed in the context of semiconductor manufacturing, and in particular, in the context of forming a semiconductor structure including a photonic integrated circuit (PIC) die and an electronic integrated circuit (EIC) die. Some variations of embodiments are discussed and the intermediate stages of forming the semiconductor structure are illustrated in accordance with some embodiments. It should be appreciated that the illustration throughout the drawings are schematic and not in scale.

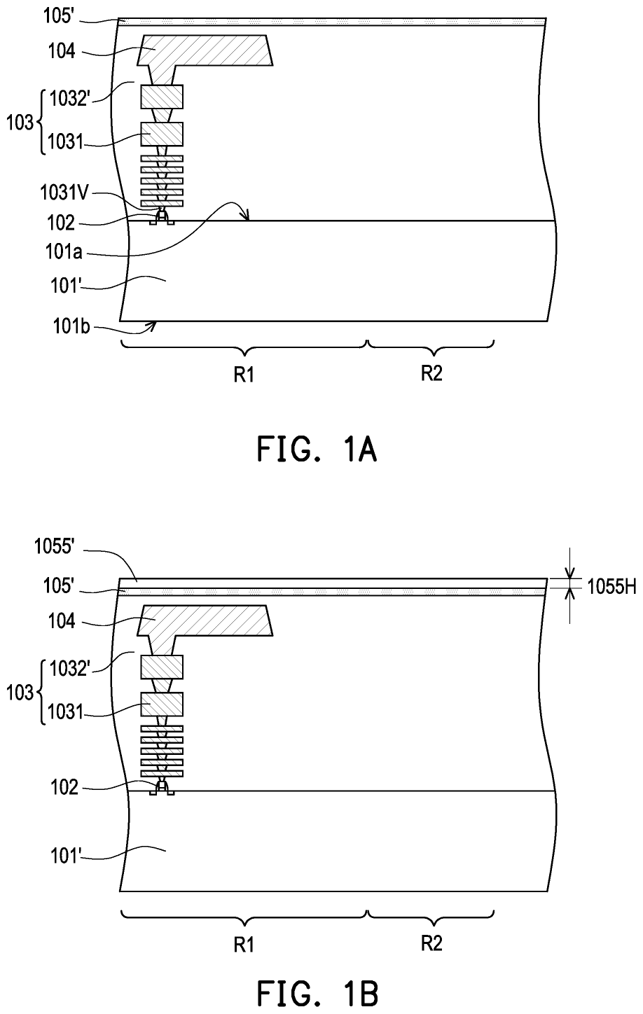

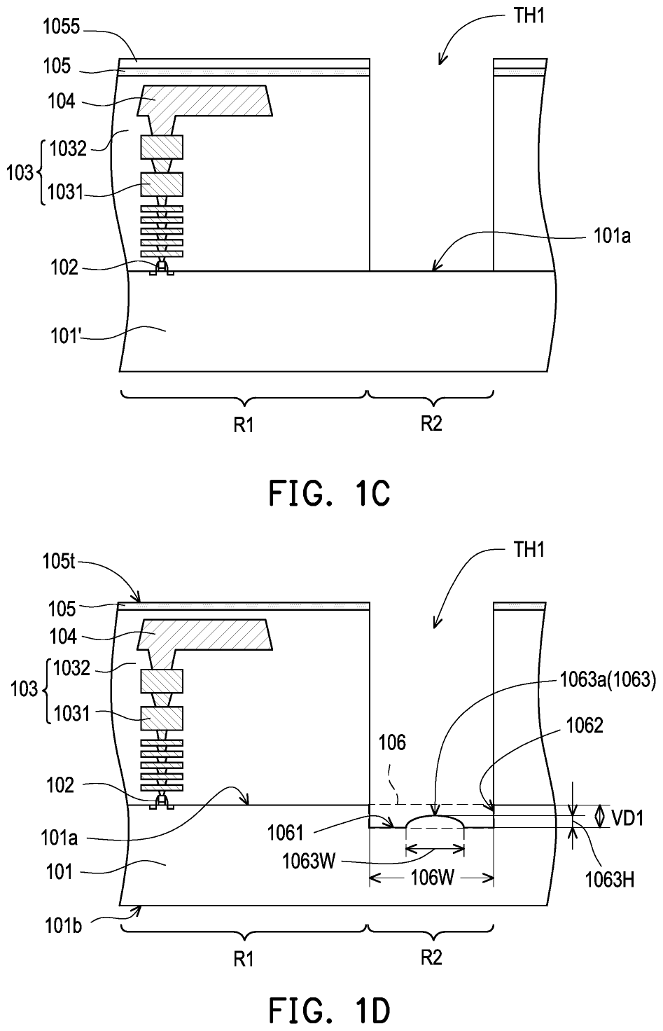

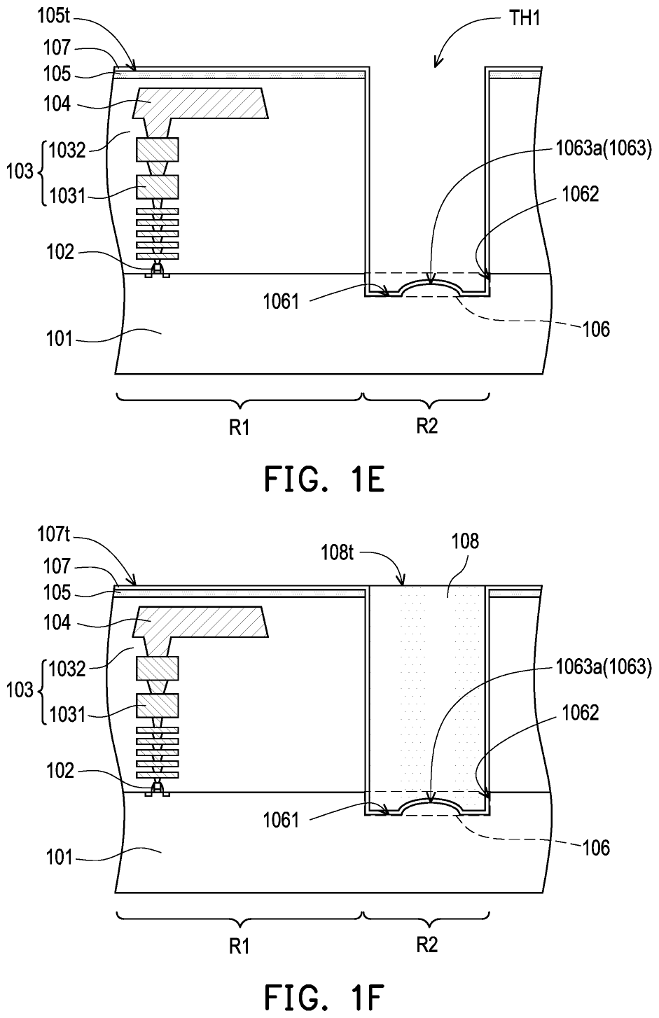

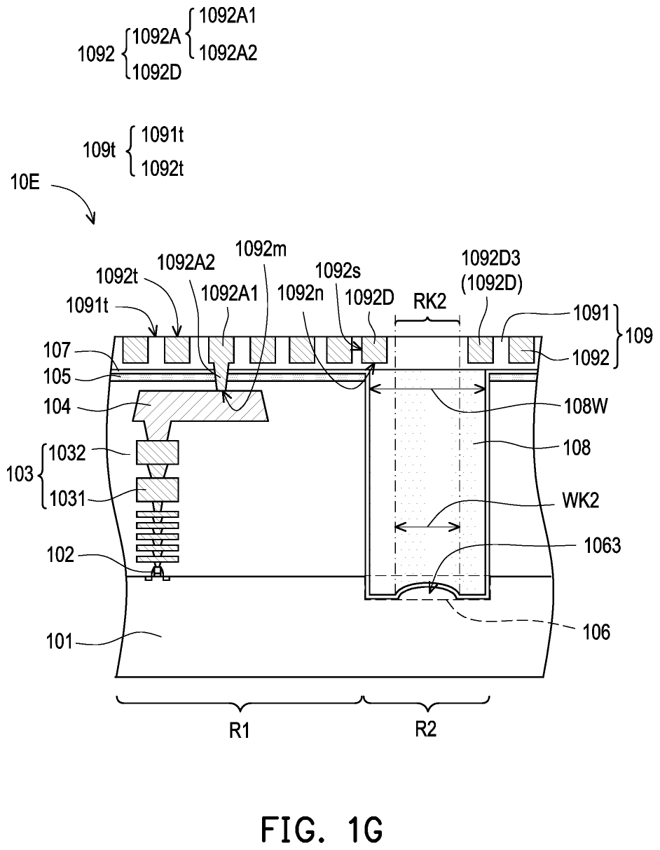

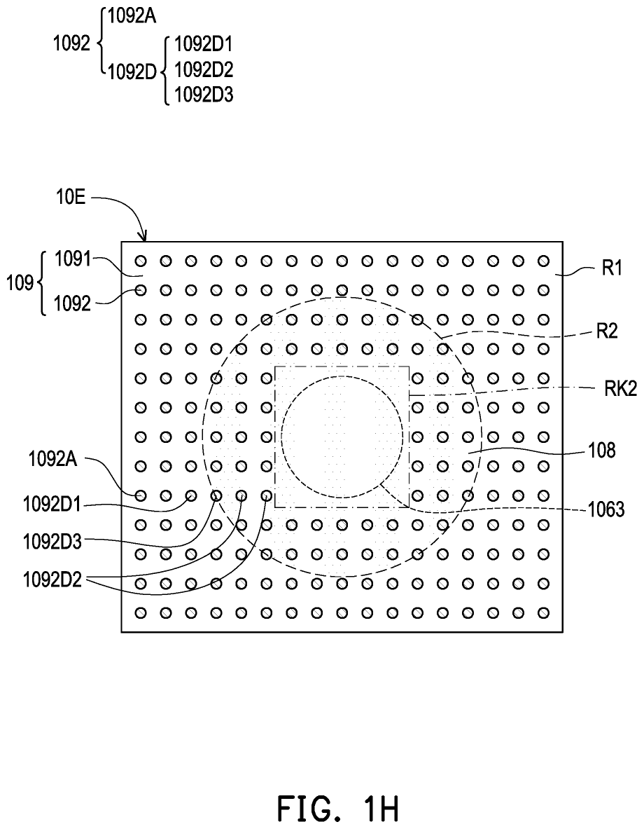

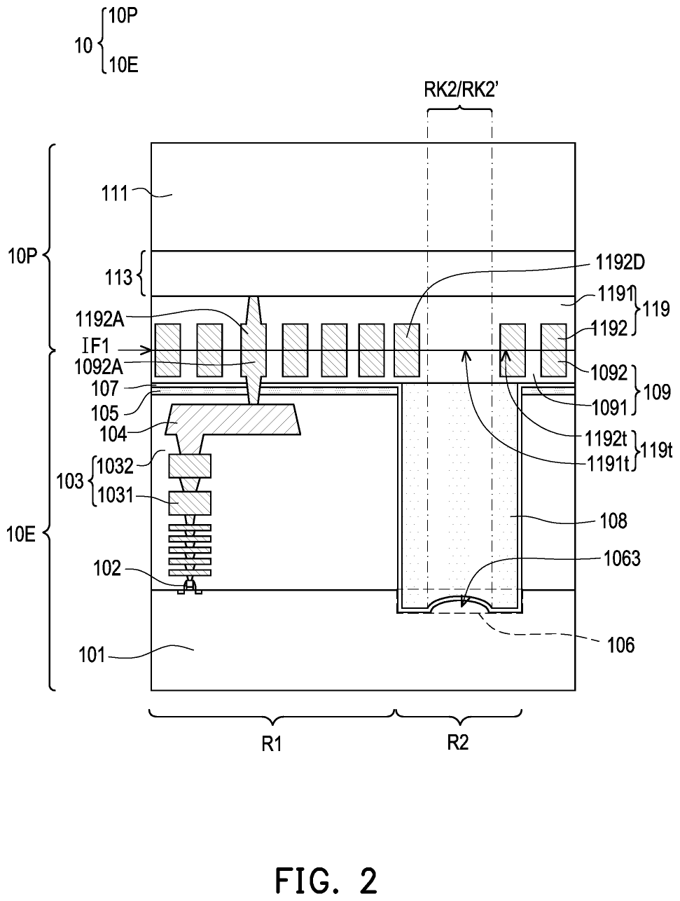

FIGS. 1A-1G illustrate schematic cross-sectional views of intermediate steps during a process for forming a first device, in accordance with some embodiments. FIG. 1H illustrates a schematic and partial top-down plan view of a first device, in accordance with some embodiments. Note that the first device in FIG. 1H is similar to the first device in FIG. 1G, except that the number of the bonding features illustrated in FIG. 1H does not correspond to the number of the bonding features illustrated in FIG. 1G. Although method embodiments may be discussed as being performed in a particular order, other method embodiments may be performed in any logical order.

Referring to FIG. 1A, a substrate 101′ having a front surface 101a and a back surface 101b may be provided. In some embodiments, the substrate 101′ includes a first region R1 and a second region R2 connected to the first region R1. For example, the first region R1 is an electrically active region, and the second region R2 is an optically active region in which the optical component(s) will be formed. One or more electrical component(s) used to transmit electric signal may be formed in/above the first region R1, and one or more optical component(s) used to transmit optical signal may be formed in/above the second region R2. It should be noted that the first region R1 may also represent the first region R1 of the first device 10E (see FIG. 1G), and the second region R2 may also represent the second region R2 of the first device 10E.

The material of the substrate 101′ is not particularly limited. For example, the substrate 101′ includes a material capable of transmitting radiation of at least one wavelength of interest. The wavelength of interest may fall in any useful region of the electromagnetic spectrum, such as in the ultraviolet range, in the visible range, or in the infrared range. In some embodiments, the wavelength of interest is more than a single wavelength, and such multiple individual wavelengths may fall in one or more of the above ranges. In some embodiments, the material of the substrate 101′ is selected based on its refractive index at the wavelength of interest. In some embodiments, the substrate 101′ is a semiconductor substrate. For example, the material of the substrate 101′ includes one or more semiconductor material(s), which may be elemental semiconductor materials (e.g., Si, Ge, or the like), compound semiconductor materials (e.g., SiC, SiGeC, or the like), or alloy semiconductor materials (e.g., SiGe, GaAsP, AlInAs, or the like). In some embodiments, the substrate 101′ is an inorganic substrate which includes one or more dielectric materials (e.g., silicon oxide, silicon nitride, silicon carbide, or the like). In some embodiments, the substrate 101′ includes one or more organic dielectrics (e.g., epoxy resin, polyimide (PI), benzocyclobutene (BCB), polybenzoxazole (PBO), or the like).

In some embodiments, one or more device 102 is formed in/on the front surface 101a of the substrate 101′. The device 102 may be or include active devices (e.g., transistors, diodes, etc.), capacitors, resistors, or the like. The device 102 may be formed through front-end-of-line (FEOL) processes and may be referred to as a FEOL device. Although the device 102 is represented by a single transistor, it should be understood that the type and the number of the device 102 construe no limitation in the disclosure. In some embodiments, an interconnect structure 103 is formed over the substrate 101′ and interconnects the device 102 to form an integrated circuit. The interconnect structure 103 may include metallization patterns 1031 formed in one or more dielectric layer(s) 1032′. The dielectric layer 1032′ may include low-k dielectric material(s) or any suitable dielectric material. The metallization patterns 1031 may include conductive lines, conductive pads, conductive vias, and/or the like. For example, when the device 102 is a transistor, the bottommost conductive via (or conductive plug) 1031V of the metallization patterns 1031 couples the gate and source/drain region of the transistor. For example, the interconnect structure 103 is formed through back-end-of-line (BEOL) processes and may be referred to as a BEOL structure.

With continued reference to FIG. 1A, one or more contact pad(s) 104 (e.g., an aluminum pad, aluminum-copper pad, or the like) may be formed on the topmost one of the metallization patterns 1031. In some embodiments, the contact pad 104 is embedded in the dielectric layer 1032′. In some embodiments, a passivation material layer 105′ is formed on the dielectric layer 1032′ and above the contact pad 104. In some embodiments, the passivation material layer 105′ includes one or more layers of silicon oxide, silicon nitride, silicon oxynitride, the like, or a combination thereof. In some embodiments the passivation material layer 105′ acts as a stop layer to stop the etching/removal process thereon.

Referring to FIG. 1B and with reference to FIG. 1A, a masking material layer 1055′ may be formed on the passivation material layer 105′. In some embodiments, the masking material layer 1055′ acts as a hard mask for patterning the substrate 101′ (see FIG. 1D). The masking material layer 1055′ may include a silicon-containing material (e.g., silicon oxide, silicon nitride, etc.), a metal-containing material (e.g., titanium nitride, titanium oxide, etc.), a combination thereof, and/or the like. The masking material layer 1055′ may have a material different from the material of the underlying passivation material layer 105′. In some embodiments, the masking material layer 1055′ includes a positive or a negative photoresist. In some embodiments, the masking material layer 1055′ is formed by depositing a layer of masking material by any suitable deposition process (e.g., spin-coating, chemical vapor deposition (CVD), etc.) and flattening the layer of masking material by any suitable process (e.g., chemical mechanical polishing (CMP), etching, a combination thereof, etc.). For example, the masking material layer 1055′ is polished to create a substantially flat surface. In some embodiments, after the flattening (e.g., polishing) process, the masking material layer 1055′ is thinned down to have a thickness 1055H (e.g., about 1 μm or less, but the present disclosure is not limited thereto). The thinner masking material layer 1055′ may allow for creating a through hole (see FIG. 1C) with an improved aspect ratio.

Referring to FIG. 1C and with reference to FIG. 1B, portions of the masking material layer 1055′, the passivation material layer 105′, and the dielectric layer 1032′ may be removed to respectively form a masking layer 1055, a passivation layer 105, and a patterned dielectric layer 1032. For example, one or more through hole(s) TH1 is formed through the masking layer 1055, the passivation layer 105, and the patterned dielectric layer 1032. In some embodiments, the through hole TH1 is formed by lithography and etching processes or any suitable removal process. The front surface 101a of the substrate 101′ may be accessibly exposed by the through hole TH1, and the through hole TH1 may be formed over and correspond to the second region R2. Although a single through hole TH1 is illustrated in the cross-sectional view of FIG. 1C, it should be understood that the dimension and the number of the through hole may vary depending on product requirements and construe no limitation in the disclosure.

Referring to FIG. 1D and with reference to FIG. 1C, the substrate 101′ accessibly exposed by the through hole TH1 may be patterned to form the substrate 101 including a pattern 106. For example, one or more etching process(es) is performed on the front surface 101a of the substrate 101′ using the masking layer 1055 as an etching mask to form the pattern 106. The pattern 106 may be recessed and located within the second region R2. The etching condition(s) may be selected so that the height level of the pattern 106 is underneath that of the device 102, relative to the back surface 101b of the substrate 101. The etching may be any acceptable etch process, such as wet or dry etching, a reactive ion etch (RIE), neutral beam etch (NBE), the like, or a combination thereof. In some embodiments, the etching is anisotropic. The masking layer 1055 may be removed to expose the top surface 105t of the passivation layer 105 during or after the patterning process of the substrate 101′, depending on the material properties of the masking layer 1055 and the process recipe of the removal process. In other embodiments, the masking layer 1055 is removed through ashing, stripping, or the like, after the patterning of the substrate. In some embodiments, the passivation layer 105 acts as an etch stop layer during the removal of the masking layer 1055.

In some embodiments, the pattern 106 has a bottommost surface 1061 below the front surface 101a of the substrate 101, a sidewall 1062 connected to the bottommost surface 1061, and one or more protrusion (or raised structure) 1063 protruding from the bottommost surface 1061. The sidewall 1062 may be substantially vertical or may be sloped with respect to the bottommost surface 1061, where the tapering angle of the sidewall 1062 is not particularly limited. In some embodiments, the protrusion 1063 acts as a lens which includes a convex top surface 1063a connected to the bottommost surface 1061. For example, the convex top surface 1063a is rounded (e.g., curved outwardly from the bottommost surface 1061). In some embodiments, the topmost point of the convex top surface 1063a is between the topmost point of the front surface 101a and the bottommost surface 1061. The convex top surface 1063a may be viewed as an optical surface. In some embodiments, the protrusion 1063 has a maximum lateral dimension 1063W less than a maximum lateral dimension 106W of the pattern 106. In some embodiments, the protrusion 1063 has a maximum height 1063H measured between the topmost point of the protrusion 1063 and the virtual plane extending from the bottommost surface 1061. The maximum height 1063H of the protrusion 1063 may be less than a vertical distance VD1 measured between the topmost point of the front surface 101a and the bottommost surface 1061.

The protrusion 1063 may have any suitable cross-sectional profile (e.g., a semicircular profile, a rectangular profile, a trapezoidal profile, a triangular profile, a bell profile, a combination thereof, the like, etc.). In some embodiments, a plurality of protrusions 1063 formed in the second region R2 has the same cross-sectional shape and may be arranged in an array. In some embodiments, more than one protrusions 1063 formed in the second region R2 have different cross-sectional shapes with respect to each other. The shape and the dimension of the protrusion 1063 may be selected according to the application requirements. In some embodiments, the pattern 106 in the second region R2 is configured to have a lensing effect on incident radiation of selected wavelength and act as a lens of a certain focal length for the incident radiation. While lensing has been described as an example, the disclosure is not limited thereto. For example, the substrate 101′ is patterned to form an optical element such as a grating coupler, a waveguide pattern, a modulator, a multiplexer, a combination thereof, and/or the like. It is appreciated that other optical effect(s) may be implemented by tuning the formation conditions of the pattern 106.

Referring to FIG. 1E and with reference to FIG. 1D, a protective layer 107 may be formed on the passivation layer 105 and in the through hole TH using any suitable approach such as CVD, ALD, sputtering, evaporation, or the like. For example, the protective layer 107 is a conformal film overlying the top surface 105t of the passivation layer 105, lining the inner sidewalls of the passivation layer 105 and the patterned dielectric layer 1032, and also overlying the pattern 106. The protective layer 107 may be a liner, and the through hole TH may be lined with the protective layer 107. In some embodiments, the protective layer 107 blanketly covers the bottommost surface 1061, the sidewall 1062, and the convex top surface 1063a of the protrusion 1063. The protective layer 107 may be a single layer or a composite layer including multiple sublayers with different materials. The protective layer 107 may be or include one or more dielectric material such as silicon oxide, silicon nitride, silicon-oxynitride, titanium nitride, or other suitable material(s). In some embodiments, the protective layer 107 is or includes a film of photo-absorptive material (e.g., an anti-reflective coating (ARC) or the like). For example, the protective layer 107 is transparent to the target light wavelength (e.g., to a light wavelength of infrared radiation). The protective layer 107 may be configured to minimize reflection of the light emitted from the optical source that enters/exits the optical component 1063 (e.g., the lens), thus reducing optical loss. In some embodiments, the protective layer 107 is or includes a stop layer to stop the polishing/etching/removal process thereon. It should be noted that the material, the index of refraction, the thickness of the protective layer 107 may be selected according to the application requirements. Alternatively, the protective layer 107 is omitted.

Referring to FIG. 1F and with reference to FIG. 1E, a filling layer 108 may be formed in the remaining space of the through hole TH1. The filling layer 108 may be formed according to any suitable process, such as CVD, PVD, ALD, or the like. In some embodiments, a planarization process (e.g., grinding, CMP, etching, a combination thereof, or the like) is performed after the material of the filling layer 108 is disposed in the through hole TH1. Following the planarization, the top surface 108t of the filling layer 108 and the top surface 107t of the protective layer 107 may be substantially leveled (or coplanar), within process variations. The material of the filling layer 108 is not particularly limited, and may be selected on the basis of its refractive index and the refractive index of the material of the protective layer 107 (if present). The filling layer 108 may be transparent to light radiation in the target wavelength range. For example, the filling layer 108 includes an inorganic material, such as an oxide (e.g., silicon oxide), a nitride, carbide, or the like. The filling layer 108 and the protective layer 107 may include the same material. In some embodiments, the filling layer 108 and the protective layer 107 includes different materials, optionally with matching refractive index to achieve desired optical effects on the incident radiation.

The protective layer 107 may be directly formed on the top surface 105t of the passivation layer 105 since the masking layer 1055 has been removed before forming the protective layer 107. The filling layer 108 may be directly formed on the protective layer 107 within the through hole TH1. It should be appreciated that the presence of the masking layer 1055 would result in higher aspect ratio of the filling layer 108 if the masking layer 1055 is not removed before forming the filling layer. By removing the masking layer 1055 before forming the filling layer 108, the maximum height 108H of the filling layer 108 in the through hole TH1 may be reduced. The processes of FIGS. 1D-1F allows lowering the aspect ratio (e.g., the maximum height 108H/the maximum lateral dimension 108W) of the filling layer 108. The improved aspect ratio of the filling layer 108 may help to achieve better optical performance.

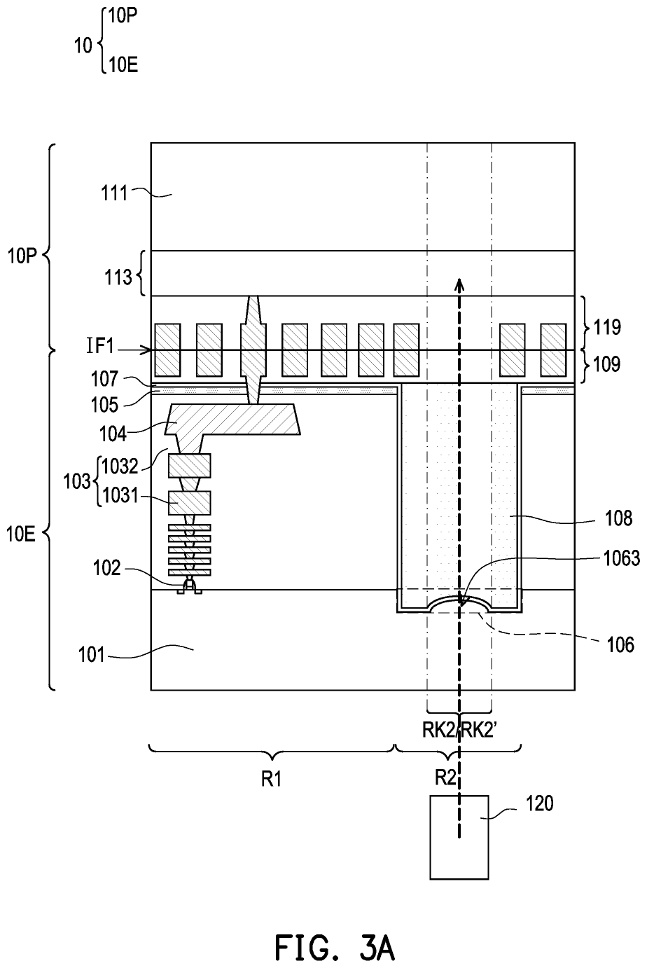

Referring to FIG. 1G and with reference to FIG. 1F, a bonding structure 109 may be formed on the protective layer 107 (if present) and the filling layer 108. For example, the bonding structure 109 includes a bonding dielectric layer 1091 and bonding features 1092 covered by the bonding dielectric layer 1091. The bonding dielectric layer 1091 may be a single layer or may include a plurality of stacked dielectric sublayers. The material of the bonding dielectric layer 1091 may include inorganic materials such as silicon oxide, silicon nitride, silicon oxynitride, silicon carbonitride, silicon oxy-carbonitride, or a combination thereof. The bonding dielectric layer 1091 may be formed by suitable fabrication techniques such as spin-on coating, CVD, ALD, PVD, or the like. The bonding features 1092 may include one or more conductive material(s) such as copper, cobalt, tungsten, titanium, tantalum, aluminum, zirconium, hafnium, alloy, a combination thereof, or other suitable metallic materials. The bonding features 1092 may be formed by damascene process (e.g., single damascene and/or dual damascene). For example, the bonding features 1092 are formed by: forming trenches in the bonding dielectric layer 1091; and filling the trenches with conductive materials through PVD, CVD, plating, a combination thereof, and/or the like. In some embodiments, a planarization process (e.g., grinding, CMP, etching, a combination thereof, or the like) is performed on the bonding structure 109. Following the planarization, the top surface 1091t of the bonding dielectric layer 1091 and the top surfaces 1092t of the bonding features 1092 may be substantially leveled (or coplanar), within process variations. The top surfaces 1091t and 1092t may be collectively viewed as a bonding surface 109t of the bonding structure 109. The structure illustrated in FIG. 1G may be viewed as a first device 10E having the optically active region R2. In some embodiments, the first device 10E is provided in wafer form. In some embodiments, the first device 10E being in wafer form is singulated to form a plurality of first dies, before a bonding process (described in FIG. 2). In some embodiments, the first die/device is viewed as an electronic (or electronic integrated circuit; EIC) die/device.

Referring to FIG. 1H and with reference to FIG. 1G, the top-down view of the first device 10E in FIG. 1G may be similar to the top-down view illustrated in FIG. 1H, except that the number of the bonding features 1092 illustrated in FIG. 1H does not correspond to the number of the bonding features 1092 illustrated in FIG. 1G. In some embodiments, the bonding features 1092 are distributed across the bonding dielectric layer 1091 in an array except for a keep-out zone RK2. The keep-out zone RK2 may be used to define a region where no bonding features (or other features/devices) could be placed within. In some embodiments, the keep-out zone RK2 is located within the second region R2 and may have a maximum lateral dimension WK2 less than the maximum lateral dimension 108W of the filler layer 108. The maximum lateral dimension WK2 of the keep-out zone RK2 may be greater than or substantially equal to the maximum lateral dimension 1063W (labeled in FIG. 1D) of the protrusion 1063. In the top-down view, the boundary of the protrusion 1063 (e.g., the optical component) may be included within the keep-out zone RK2 to ensure that the protrusion 1063 does not be blocked when transmitting radiation. In the illustrated embodiment, the keep-out zone RK2 has a rectangular (or square) top-view shape, and the protrusion 1063 has a circular (or ellipse) top-view shape. Other shapes and dimensions are possible, and the keep-out zone RK2 and the protrusion 1063 may have a different number and arrangement than shown.

With continued reference to FIGS. 1G-1H, the bonding features 1092 may include one or more active feature(s) 1092A electrically and physically connected to the contact pad 104 (and/or the metallization patterns 1031 of the interconnect structure 103). For example, the respective active feature 1092A includes a pad portion 1092A1 and a via portion 1092A2 connected to the pad portion 1092A1 and the contact pad 104, where the pad portion 1092A1 is inlaid in the bonding dielectric layer 1091. The respective via portion 1092A2 may pass through the bonding dielectric layer 1091, the protective layer 107, the passivation layer 105, and the patterned dielectric layer 1032. The bottom surface 1092m of the respective via portion 1092A2 may be connected to the contact pad 104. The via portion 1092A2 may be tapered in a direction same as the conductive vias of the metallization patterns 1031 of the interconnect structure 103. In alternative embodiments, the respective active feature 1092A is a conductive via which has the wider top exposed by the bonding dielectric layer 1091 and the narrower bottom landing on the contact pad 104. In the illustrated embodiment, the active features 1092A have a circular (or ellipse) top-view shape, and all (or substantially all) of the active feature 1092A may have a same top-view shape, a same top-view size, and/or a same pitch to have a uniform pattern density throughout the first device 10E. Other shapes are possible, and the active features 1092A may have a different number and arrangement than shown.

With continued reference to FIGS. 1G-1H, the bonding features 1092 may include one or more dummy feature(s) 1092D electrically isolated from the active feature 1092A. For example, the dummy features 1092D are electrically floating. In some embodiments, the respective dummy feature 1092D is a conductive pad (or a bonding pad) which has a top surface 1092t exposed by the bonding dielectric layer 1091, and a bottom surface 1092n and a sidewall 1092s of the dummy feature 1092D are physically covered by the bonding dielectric layer 1091. By configuring the dummy features 1092D, the pattern-loading effect and dishing effect may be reduced, and the bonding surface 109t may be more planar to facilitate the subsequent bonding process (see FIG. 2). In the illustrated embodiment, the dummy features 1092D have a circular (or ellipse) top-view shape, and all (or substantially all) of the dummy features 1092D and the active features 1092A may have a same top-view shape, a same top-view size, and/or a same pitch. By configuring the dummy features 1092D having the top-view shape/size/pitch substantially identical to those of the active features 1092A, a more uniform pattern density may be achieved across the bonding surface 109t of the first device 10E to facilitate the subsequent bonding process. Other shapes, sizes, and pitches are possible, and the dummy features 1092D may have a different number and arrangement than shown.

In some embodiments, the dummy features 1092D include one or more first feature(s) 1092D1 disposed right over the first region R1 and may be disposed alongside (or surround) the active features 1092A to increase metal density within the first region R1. The first features 1092D1 may be separated from the protective layer 107 by the bonding dielectric layer 1091. By configuring the first features 1092D1 over the first region R1, a uniform pattern density throughout the first region R1 may be achieved, thereby facilitating the subsequent bonding process. In some embodiments, the dummy features 1092D include one or more second feature(s) 1092D2 disposed over the second region R2 and outside the keep-out zone RK2. By configuring the second features 1092D2 over the second region R2 and outside the keep-out zone RK2, the bonding features 1092 may have a more uniform pattern density and a more uniform pitch in both of the first and second regions R1 and R2, while maintaining the optical path without being shielded.

Still referring to FIGS. 1G-1H, the dummy features 1092D may include one or more third feature(s) 1092D3 disposed directly over the intersection of the first region R1 and the second region R2. For example, in the top-down view, the vertical projection of the third feature 1092D3 directly overlies the boundary of the filling layer 108 and an interface of the filling layer 108 and the protective layer 107. In the cross-sectional view, the third feature 1092D3 may be spatially separated from the filling layer 108 and the protective layer 107 through the bonding dielectric layer 1091. It is appreciated that the materials among the bonding dielectric layer 1091, the filling layer 108, and the protective layer 107 may be different, and a difference is among an etch rate of the bonding dielectric layer 1091, an etch rate of the filling layer 108, and an etch rate of the protective layer 107. It is difficult to control etch uniformity when etching the openings at the intersection of the bonding dielectric layer 1091, the filling layer 108, and the protective layer 107, where the third features 1092D3 are to be formed in the openings. Since the dummy features 1092D are formed in the openings of the bonding dielectric layer 1091 without extending to be in direct contact with the filling layer 108 and the protective layer 107, a more uniform profile of the dummy features 1092D (especially the third features 1092D3) may be achieved.

FIG. 2 illustrates a schematic cross-sectional view of forming a semiconductor structure with the first die bonded to a second die according to some embodiments. Unless specified otherwise, the materials of the components in these embodiments are essentially the same as the like components, which are denoted by like reference numerals in the embodiments shown in FIGS. 1A-1H.

Referring to FIG. 2 and with reference to FIG. 1G, a semiconductor structure 10 includes a second die 10P stacked upon and bonded to the first die 10E. The semiconductor structure 10 may have the EIC-PIC integration with the electrical interface designed to minimize the coupling loss. For example, the first die 10E is an electronic (or EIC) die, while the second die 10P is a photonic (or photonic integrated circuit; PIC) die. The first die 10E may be similar to the first device described in FIGS. 1G-1H. The second die 10P may include any semiconductor photonic integrated circuit. For example, the second die 10P includes a substrate 111 and an electro-optical circuit structure 113 formed over the substrate 111. The material of the substrate 111 may be similar to that of the substrate 101 of the first die 10E. The electro-optical circuit structure 113 may be configured to integrate multiple photonic functions for optical information signals received thereby via, e.g., optical fibers. The electro-optical circuit structure 113 may be configured to converting the optical signals to electrical signals or vice versa. In some embodiments, the second die 10P includes one or more active and/or passive optical devices (not individually shown) responsible for the I/O of optical signals to/from the optical signal port. The active and/or passive optical devices may include couplers, lasers, optical modulators, detectors, waveguides, splitters, converters, switches, etc. In some embodiments, the optical devices are formed in the electro-optical circuit structure 113 to guide light/signals from the optical signal port coupled thereto.

In some embodiments, the second die 10P includes a bonding structure 119 formed over the electro-optical circuit structure 113. The bonding structure 119 may be similar to the bonding structure 109 of the first die 10E. For example, the bonding structure 119 includes a bonding dielectric layer 1191 and bonding features 1192 covered by the bonding dielectric layer 1191. The materials and forming methods of the bonding dielectric layer 1191 and the bonding features 1192 may be similar to those of the bonding dielectric layer 1091 and the bonding features 1092, respectively. The bonding features 1192 may include active features 1192A and dummy features 1192D. The active features 1192A may be similar to the active features 1092A, and the dummy features 1192D may be similar to the dummy features 1092D. In some embodiments, the first die 10E and the second die 10P are electrically connected through the active features (1192A and 1092A). For example, the first die 10E receives and processes the electrical signals generated by the second die 10P upon detection of incident radiation. In some embodiments, the distribution layout of the bonding features 1192 of the second die 10P corresponds to that of the bonding features 1092 of the first die 10E. For example, the second die 10P includes a keep-out zone RK2′ in which no conductive features are formed to ensure that the conductive features in the second die 10P do not block the optical path. The first die 10E and the second die 10P may be optically coupled to each other in the second region R2 (e.g., the optically active region). For example, the second die 10P converts the optical signal from the optical signal port into electric signal and transmits the electric signal to the first die 10E.

The outermost surface 1191t of the bonding dielectric layer 1191 and the outermost surfaces 1192t of the bonding features 1192 may be substantially leveled (or coplanar) to facilitate the bonding process. The outermost surfaces 1191t and 1192t may be collectively viewed as a bonding surface 119t of the bonding structure 119. For example, the bonding involves the wafer-to-wafer bonding. In such embodiments, the EIC wafer and the PIC wafer are bonded together, and then a singulation process is performed to form individual semiconductor structures 10, where the lateral dimension of the first die 10E is substantially equal to that of the second die 10P. In some other embodiments, the bonding involves the die-to-wafer bonding, and one of the EIC wafer and the PIC wafer is singulated into individual dies having a required size, and then the singulated die is bonded to the other one of the EIC wafer and the PIC wafer, where the singulated die is smaller than the wafer in the lateral size.

With continued reference to FIG. 2 and FIG. 1G, the bonding process may include the following steps in accordance with some embodiments. For example, surface preparation (e.g., cleaning, activation, a combination thereof, etc.) for the bonding surfaces (119t and 109t) to be bonded may be performed. After the surface preparation, the second die (or wafer) 10P may be substantially aligned with the first die (or wafer) 10E. For example, each bonding feature 1191 of the second die (or wafer) 10P may be substantially aligned with the corresponding bonding feature 1091 of the first die (or wafer) 10E. The keep-out zone RK2′ of the second die (or wafer) 10P may be substantially aligned with the keep-out zone RK2 of the first die (or wafer) 10E. Next, the bonding surface119t of the bonding structure 119 may be in contact with the bonding surface 109t of the bonding structure 109. After bringing the second die (or wafer) 10P to be in contact with the first die (or wafer) 10E, the bonding process may be performed. For example, the bonding process includes thermal treatment for dielectric bonding and thermal annealing for conductor bonding. After the thermal annealing, the bonding dielectric layers (1191 and 1091) may be fused together, and the bonding features (1192 and 1092) may be bonded together. When the keep-out zone RK2′ is substantially aligned to the keep-out zone RK2, and bonded thereto, the bond yield of the first and second dies (or wafers) may be improved, while maintaining the optical path in the semiconductor structure 10 without being blocked.

The bonds at the bonding interface IF1 of the first die (or wafer) 10E and the second die (or wafer) 10P may include dielectric-to-dielectric bonds (e.g., oxide-to-oxide bonds), metal-to-metal bonds (e.g., copper-to-copper bonds), metal-to-dielectric bonds (e.g., copper-to-oxide bonds), any combinations thereof, and/or the like. The bonding interface IF1 may be substantially planar and/or flat. It should be noted that pad-to-pad bonding illustrated herein is merely an example, and via-to-via bonding or via-to-pad bonding may be employed in accordance with some embodiments. It should be appreciated that while the bonding has been described to connect the second die (or wafer) 10P to the first die (or wafer) 10E, alternative connection schemes are also possible, with corresponding adaptations to the bonding interface.

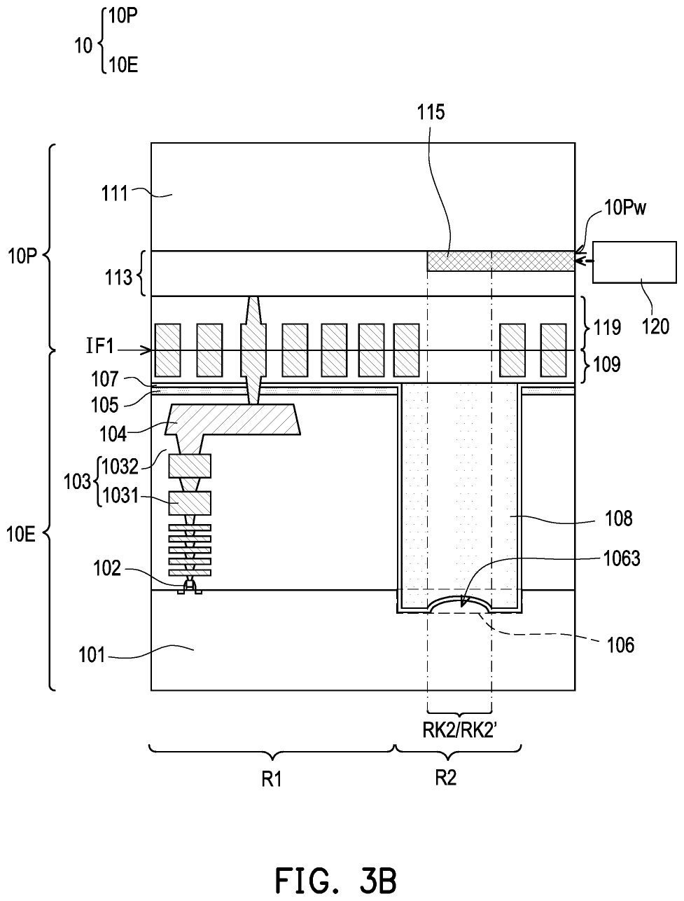

FIGS. 3A and 3B illustrate schematic cross-sectional views of the semiconductor structure optically coupled to an optical signal port according to some embodiments. Unless specified otherwise, the materials of the components in these embodiments are essentially the same as the like components, which are denoted by like reference numerals in the embodiments shown in FIGS. 1H and 2.

Referring to FIG. 3A and with reference to FIG. 2, an optical signal port 120 may be optically coupled to the semiconductor structure 10. The semiconductor structure 10 may be similar to the semiconductor structure described in FIG. 2. The optical signal port 120 may be an optical input/output (I/O) port where optical signals may enter and/or exit. For example, the optical signal port 120 includes at least one fiber facing the optical component(s) in the semiconductor structure 10. In some embodiments, the optical signal port 120 includes a plurality of fibers arranged in an array, and a plurality of the optical components 1063 arranged in an array may be optically coupled to the fiber array in a one-to-one correspondence. In some embodiments, the optical signal port 120 is attached to the backside of the substrate 101 of the first die 10E through, for example, an optical adhesive or the like (not shown). Other fixing mechanism may be applied depending on product requirements.

In some embodiments, light beam which carries the optical signal from the optical signal port 120 passes through the substrate 101, the protective layer 107 (if present), the filling layer 108, the bonding structure 109 in sequence toward the second die 10P. In some embodiments, the optically active region R2 has a lensing effect on incident radiation of selected wavelength. For example, the protrusion 1063 in the optically active region R2 acts as an optical component (e.g., a lens) of a certain focal length for the incident radiation. In some embodiments, the optical signal port 120 is disposed directly underneath the optically active region R2 and optically aligned with the optical component 1063 in the first die 10E. The optical component 1063 acting as a lens (or a focusing member) may be utilized to guide the light from the optical signal port 120 to the second die 10P. The optical component 1063 may have a predetermined focal length that is capable of focusing light onto the second die 10P. The second die 10P may convert the optical signal from the optical signal port 120 into electric signal and transmit the electric signal to the first die 10E. In some other embodiments, the optical signal port 120 is disposed directly over the second die 10P and optically aligned with the optical component 1063. It should be noted that the transmission path is outlined in the dashed arrow as an example and can be adjusted depending on the position/shape/configuration of the optical component 1063 and application requirements. Also, the optical signal port 120 may have a different configuration than shown.

Referring to FIG. 3B and with reference to FIG. 3A, the structure shown in FIG. 3B is similar to the structure shown in FIG. 3A. The difference therebetween includes that the optical signal port 120 is optically aligned with the sidewall 10Pw of the second die 10P. For example, a light-guiding element 115 (e.g., an edge coupler, a waveguide, a grating coupler, a reflector, the like, a combination thereof, or any suitable optics) is disposed at the sidewall 10Pw optically aligned with the optical signal port 120. The light-guiding element 115 may be embedded in the electro-optical circuit structure 113 or may be integrated into the substrate 111. In some embodiments, light beam which carries the optical signal from the optical signal port 120 enters the second die 10P, being guided by the light-guiding element 115, passing through the electro-optical circuit structure 113, the bonding structures 119 and 109, the filling layer 108, and the protective layer 107 (if present) in sequence. The optical input is outlined in the dashed arrow as an example. While lensing has been described in FIGS. 3A-3B as examples, the disclosure is not limited thereto, and other optical effects or combinations thereof may be implemented by tuning the shape of the protrusion 1063 to define the pattern 106 in the optically active region R2. For example, the optically active region R2 has a lensing effect, a polarizing effect, a filtering effect, a combination thereof, or the like. The semiconductor structure 10 including the second die 10P bonded to the first die 10E may have the flexibility to be integrated with a package component to form a semiconductor package. For example, the semiconductor structure 10 is a part of a photonic processing system that combines photonic components into a single compact unit.

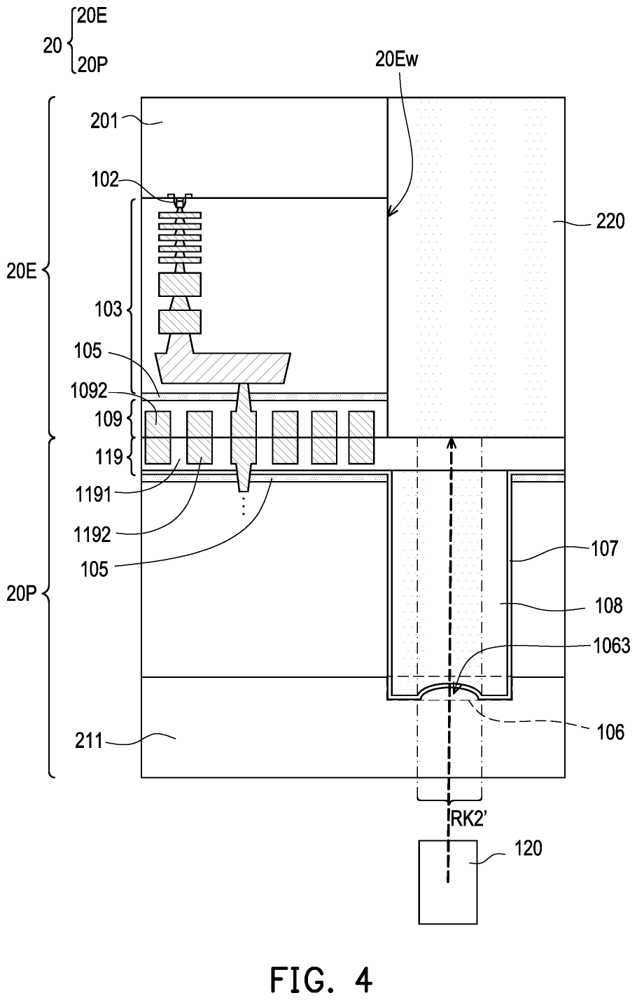

FIG. 4 illustrates a schematic cross-sectional view of a semiconductor structure optically coupled to an optical signal port according to some embodiments. Unless specified otherwise, the materials of the components in these embodiments are essentially the same as the like components, which are denoted by like reference numerals in the embodiments shown in FIGS. 1H, 2, and 3A-3B.

Referring to FIG. 4 and with reference to FIGS. 1H, 2, and 3A-3B, a semiconductor structure 20 including an first die 20E bonded to a second die 20P is provided. The first die 20E may be similar to the first die 10E. In some embodiments, the first die 20E is an electronic (or EIC) die. For example, the first die 20E includes a substrate 201, one or more device 102 formed in/on the substrate, the interconnect structure 103 formed over the substrate 201 and electrically connected to the device 102, the passivation layer 105 formed on the interconnect structure 103, and the bonding structure 109 formed on the passivation layer 105 and electrically connected to the interconnect structure 103. The substrate 201 of the first die 20E may be similar to the substrate 101 of the first die 10E, except that the substrate 201 may be free of the pattern 106. In some embodiments, the first die 20E is free of the pattern 106, the protective layer 107, and the filling layer 108. The second die 20P may be similar to the second die 10P. In some embodiments, the second die 20P is a photonic (or PIC) die. In some embodiments, the second die 20P includes a substrate 211 having the pattern 106, the protective layer 107 lining the pattern 106, the filling layer 108 overlying the protective layer 107 and directly over the pattern 106, and the bonding structure 119 bonded to the bonding structure 109 of the first die 20E. The substrate 211 may be similar to the substrate 101 described previously. The second die 20P may be electrically coupled to the first die 20E through the bonding features 1192 and 1092. The forming methods and materials of the pattern 106, the protective layer 107, and the filling layer 108 may be similar to those of the pattern 106, the protective layer 107, and the filling layer 108 described in FIGS. 1D-1F.

In some embodiments, the protrusion 1063 of the pattern 106 acts as an optical component (e.g., a lens or any suitable optics). The second die 20P may include the keep-out zone RK2′ in which the protrusion 1063 is formed. The filling layer 108, the optical component 1063, and the protective layer 107 (if present) may be collectively viewed as an optical module, and the optical module may be implemented as a part of integrated photonic engine on the first die and/or the second die according to the application requirements. In some embodiments, the first die 20E is smaller than the second die 20P in the lateral size, and an insulating layer 220 is formed on the second die 20P and covers the sidewall 20Ew of the first die 20E. The insulating layer 220 may be or include one or more insulating materials (e.g., oxides, nitrides, carbides, a combination thereof, etc.). For example, the insulating layer 220 includes a material such as a polymer that allows light transmission. The insulating layer 220 may be fused to the bonding dielectric layer 1191 and disposed directly over the filling layer 108. For example, the interface of the sidewall 20Ew of the first die 20E and the insulating layer 220 is laterally offset from the boundary of the filling layer 108 (or at least the keep-out zone RK2′) to ensure that the optical path will not be shielded or blocked.

In some embodiments, the optical signal port 120 is optically coupled to the semiconductor structure 20. For example, the optical signal port 120 is optically aligned with the optical component (e.g., the lens) 1063 in the second die 20P. In some embodiments, light beam which carries the optical signal from the optical signal port 120 passes through the insulating layer 220, the bonding structure 119, the filling layer 108, and the protective layer 107 (if present) in sequence. The transmission path is outlined in the dashed arrow as an example. For example, the light beam from the optical signal port 120 passes through the optical element 1063 can incident on the optical device(s) in the second die 20P (or first die 20E) in a desirable manner. The second die 20P may convert the optical signal from the optical signal port 120 into electric signal and transmit the electric signal to the first die 20E. It should be noted that the optical signal port 120, the transmission path, and the semiconductor structure 20 may have a different arrangement than shown.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a semiconductor structure includes a substrate, a bonding structure disposed over the substrate, and a filling layer. The substrate includes an optically active region and an optical surface in the optically active region. The bonding structure includes a bonding dielectric layer and conductive features in the bonding dielectric layer and arranged outside a keep-out zone of the bonding structure, where in a first view, the keep-out zone is located in the optically active region, and a first feature of the conductive features is disposed between the optically active region and the keep-out zone. The filling layer is interposed between the bonding structure and the optically active region of the substrate. The first feature is separated from the filling layer by the bonding dielectric layer in a second view.

According to some alternative embodiments, a semiconductor structure includes a substrate, a dielectric layer, a filling layer, and a first bonding structure disposed over the dielectric layer and the filling layer. The substrate includes a first side, a second side opposite to the first side, and a pattern at the first side, and a portion of the pattern acts as an optical component. The dielectric layer is disposed on the first side of the substrate and includes a through hole corresponding to the pattern of the substrate. The filling layer is disposed in the through hole of the dielectric layer and over the pattern of the substrate. The first bonding structure includes a first bonding dielectric layer and first conductive features inlaid in the first bonding dielectric layer, the first conductive features are disposed over the dielectric layer and the filling layer and arranged outside a keep-out zone below which the optical component is disposed. The first conductive features include a dummy feature isolated from the filling layer by the first bonding dielectric layer.

According to some alternative embodiments, a manufacturing method of a semiconductor structure includes: forming a dielectric layer on a substrate; forming a through hole in the dielectric layer to expose a portion of the substrate; patterning the portion of the substrate to form an optical surface; forming a filing layer in the through hole of the dielectric layer and over the optical surface of the substrate; and forming a bonding structure over the dielectric layer and the filling layer, where the bonding structure includes a bonding dielectric layer and conductive features in the bonding dielectric layer, the conductive features are arranged outside a keep-out zone below which the optical surface of the substrate is formed, and the conductive features include a dummy feature isolated from the filling layer by the bonding dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate comprising an optically active region and an optical surface in the optically active region;
a bonding structure disposed over the substrate, the bonding structure comprising a bonding dielectric layer and conductive features in the bonding dielectric layer and arranged outside a keep-out zone of the bonding structure, wherein in a first view, the keep-out zone is located in the optically active region, and a first feature of the conductive features is disposed between the optically active region and the keep-out zone; and
a filling layer interposed between the bonding structure and the optically active region of the substrate, wherein the first feature is separated from the filling layer by the bonding dielectric layer in a second view.

2. The semiconductor structure of claim 1, further comprising:
an electrical device disposed at a same side of the substrate as the optical surface; and
an interconnect structure disposed between the substrate and the bonding structure and electrically coupled to the electrical device and the bonding structure, wherein the filling layer penetrates through the interconnect structure.

3. The semiconductor structure of claim 2, wherein the conductive features comprises a second feature penetrating through the bonding dielectric layer and landing on a metallic pattern of the interconnect structure.

4. The semiconductor structure of claim 1, further comprising:
a protective layer conformally covering the optical surface of the substrate to separate the filling layer from the optical surface of the substrate.

5. The semiconductor structure of claim 4, wherein the protective layer is an anti-reflective coating film.

6. The semiconductor structure of claim 1, wherein the first feature overlaps a boundary of the filling layer in the first view.

7. The semiconductor structure of claim 1, wherein the first feature of the conductive features is a dummy pad which is electrically floating.

8. The semiconductor structure of claim 1, wherein a topmost point of the optical surface is between a topmost point of the substrate and a bottommost point of the substrate.

9. The semiconductor structure of claim 1, wherein the optical surface comprises a lens shape in the second view.

10. The semiconductor structure of claim 1, wherein bonding surfaces of the bonding dielectric layer and the conductive features facing away the substrate are substantially level.

11. A semiconductor structure, comprising:
a substrate comprising a first side, a second side opposite to the first side, and a pattern at the first side, a portion of the pattern acting as an optical component;
a dielectric layer disposed on the first side of the substrate and comprising a through hole corresponding to the pattern of the substrate;
a filling layer disposed in the through hole of the dielectric layer and over the pattern of the substrate; and
a first bonding structure disposed over the dielectric layer and the filling layer, the first bonding structure comprising a first bonding dielectric layer and first conductive features inlaid in the first bonding dielectric layer, the first conductive features being disposed over the dielectric layer and the filling layer and arranged outside a keep-out zone below which the optical component is disposed, wherein the first conductive features comprise a dummy feature isolated from the filling layer by the first bonding dielectric layer.

12. The semiconductor structure of claim 11, further comprising:
an anti-reflective coating layer conformally covering the pattern of the substrate to separate the filling layer from the pattern of the substrate.

13. The semiconductor structure of claim 11, further comprising:
interconnect traces embedded in the dielectric layer and electrically coupled to the first conductive features.

14. The semiconductor structure of claim 11, wherein the pattern of the substrate comprises a protrusion having a convex surface and acting as a lens.

15. The semiconductor structure of claim 11, wherein:
the substrate, the dielectric layer, the filling layer, and the first bonding structure are a part of a first die, and
the semiconductor structure further comprises a second die stacked upon the first die and comprising a second bonding structure, the second bonding structure comprising a second bonding dielectric layer bonded to the first bonding dielectric layer and second conductive features bonded to the first conductive features.

16. The semiconductor structure of claim 15, wherein the first die is an electronic die and the second die is a photonic die.

17. A manufacturing method of a semiconductor structure, comprising:
forming a dielectric layer on a substrate;
forming a through hole in the dielectric layer to expose a portion of the substrate;
patterning the portion of the substrate to form an optical surface;
forming a filing layer in the through hole of the dielectric layer and over the optical surface of the substrate; and
forming a bonding structure over the dielectric layer and the filling layer, wherein the bonding structure comprises a bonding dielectric layer and conductive features in the bonding dielectric layer, the conductive features are arranged outside a keep-out zone below which the optical surface of the substrate is formed, and the conductive features comprise a dummy feature isolated from the filling layer by the bonding dielectric layer.

18. The manufacturing method of claim 17, further comprising:
lining the through hole of the dielectric layer and the optical surface of the substrate with a protective layer before forming the filling layer.

19. The manufacturing method of claim 17, further comprising:
planarizing the filling layer before forming the bonding structure.

20. The manufacturing method of claim 17, further comprising:
planarizing the bonding dielectric layer and the conductive features to level bonding surfaces of the bonding dielectric layer and the conductive features.
